(19) United States
(12) Patent Application Publication
(10) Pub. No.: US 2024/0016012 A1
(43) Pub. Date: Jan. 11, 2024

(54) DISPLAY DEVICE AND METHOD FOR MANUFACTURING THE SAME

(71) Applicant: Samsung Display Co., LTD., Yongin-si (KR)

(72) Inventors: DAWOON JUNG, Yongin-si (KR); Yu-Gwang JEONG, Yongin-si (KR); Su Bin BAE, Yongin-si (KR); Tae Wook KANG, Yongin-si (KR)

(21) Appl. No.: 18/321,621

(22) Filed: May 22, 2023

(30) Foreign Application Priority Data
Jul. 8, 2022 (KR) 10-2022-0084469

(51) Int. Cl. H10K 59/131; H10K 59/12; H10K 59/124

(52) U.S. Cl. CPC H10K 59/131; H10K 59/1201; H10K 59/124

(57) ABSTRACT

A display device includes: a substrate; a semiconductor on the substrate; a first gate insulating layer on the semiconductor; a gate electrode on the first gate insulating layer, and overlapping with the semiconductor; a signal line spaced from the gate electrode; a sacrificial layer on the signal line, and including an amorphous silicon material; an interlayer insulating layer on the gate electrode and the sacrificial layer; a source electrode on the interlayer insulating layer, and connected to a first region of the semiconductor; a drain electrode on the interlayer insulating layer, and connected to a second region of the semiconductor; and a connecting member on the interlayer insulating layer, and connected to the signal line.

### CROSS-REFERENCE TO RELATED APPLICATION

This application claims priority to and the benefit of Korean Patent Application No. 10-2022-0084469, filed in the Korean Intellectual Property Office on Jul. 8, 2022, the entire content of which is incorporated by reference herein.

### BACKGROUND

### 1. Field

Aspects of embodiments of the present disclosure relate to a display device, and a manufacturing method of the display device.

### 2. Description of the Related Art

A display device serves to display a screen, and includes a liquid crystal display, an organic light emitting diode display, and the like. The display device is used in various electronic devices, such as mobile phones, navigation units, digital cameras, electronic books, portable game machines, and various terminals.

The organic light emitting diode display has a self-luminance characteristic, and unlike a liquid crystal display device, because it does not require a separate light source, a thickness and weight of the organic light emitting diode display may be reduced. In addition, the organic light emitting diode device has high-quality characteristics, such as low power consumption, high luminance, and high response speeds.

The above information disclosed in this Background section is for enhancement of understanding of the background of the present disclosure, and therefore, it may contain information that does not constitute prior art.

### SUMMARY

An organic light emitting diode display includes a plurality of pixels including an organic light emitting diode that is a self-emission element, and a plurality of transistors and one or more capacitors that are formed in each pixel to drive the organic light emitting diode. In addition, various wires are formed to transmit a voltage (e.g., a predetermined voltage) to each pixel.

An insulating layer may be disposed between a plurality of layers constituting a transistor, and between various wires. An opening may be formed in the insulating layer, and in a process of forming the opening, some exposed layers or wires may be damaged or disconnected.

Embodiments of the present disclosure are directed to a display device and a manufacturing method of the display device, in which damage to wires and/or the like may be prevented or substantially prevented from occurring in a manufacturing process.

According to one or more embodiments of the present disclosure, a display device includes: a substrate; a semiconductor on the substrate; a first gate insulating layer on the semiconductor; a gate electrode on the first gate insulating layer, and overlapping with the semiconductor; a signal line spaced from the gate electrode; a sacrificial layer on the signal line, and including an amorphous silicon material; an interlayer insulating layer on the gate electrode and the sacrificial layer; a source electrode on the interlayer insulating layer, and connected to a first region of the semiconductor; a drain electrode on the interlayer insulating layer, and connected to a second region of the semiconductor; and a connecting member on the interlayer insulating layer, and connected to the signal line.

In an embodiment, the display device may further include: a second gate insulating layer on the gate electrode; and a storage electrode on the second gate insulating layer, and overlapping with the gate electrode. The signal line may include: a first signal line at a same layer as that of the gate electrode; and a second signal line at a same layer as that of the storage electrode.

In an embodiment, the sacrificial layer may include: a first sacrificial layer directly on the first signal line; and a second sacrificial layer directly on the second signal line.

In an embodiment, the first sacrificial layer may be further directly on the gate electrode; and the second sacrificial layer may be further directly on the storage electrode.

In an embodiment, the first sacrificial layer may have same planar shapes as those of the gate electrode and the first signal line; and the second sacrificial layer may have same planar shapes as those of the storage electrode and the second signal line.

In an embodiment, the connecting member may include: a first connecting member connected to the first signal line; and a second connecting member connected to the second signal line. The first connection member may extend through the interlayer insulating layer, the second gate insulating layer, and the first sacrificial layer to be connected to the first signal line. The second connection member may extend through the interlayer insulating layer and the second sacrificial layer to be connected to the second signal line.

In an embodiment, a bottom surface of the first connecting member may be in contact with the first signal line, and a side surface of the first connecting member may be surrounded by the interlayer insulating layer, the second gate insulating layer, and the first sacrificial layer; and a bottom surface of the second connecting member may be in contact with the second signal line, and a side surface of the second connecting member may be surrounded by the interlayer insulating layer and the second sacrificial layer.

In an embodiment, the first sacrificial layer and the second sacrificial layer may be on an entirety of the substrate.

In an embodiment, the sacrificial layer may be directly on the second signal line and the storage electrode.

In an embodiment, the signal line may include: a lower signal line including aluminum; and an upper signal line on the lower signal line, and including titanium.

According to one or more embodiments of the present disclosure, a manufacturing method of a display device, includes: forming a semiconductor on a substrate; forming a first gate insulating layer on the semiconductor; forming a gate electrode on the first gate insulating layer; forming a signal line spaced from the gate electrode; forming a sacrificial layer on the gate electrode and the signal line by using an amorphous silicon material; forming an interlayer insulating layer on the sacrificial layer; and forming a source electrode, a drain electrode, and a connecting member on the interlayer insulating layer. The source electrode is connected to a first region of the semiconductor, the drain electrode is connected to a second region of the semiconductor, and the connecting member is connected to the signal line.

In an embodiment, the method may further include: forming a second gate insulating layer on the gate electrode; and forming a storage electrode on the second gate insulating layer to overlap with the gate electrode. The signal line may include: a first signal line formed in a same process as that of the forming of the gate electrode; and a second signal line formed in a same process as that of the forming of the storage electrode.

In an embodiment, the sacrificial layer may include: a first sacrificial layer directly on the first signal line; and a second sacrificial layer directly on the second signal line.

In an embodiment, the gate electrode, the first signal line, and the first sacrificial layer may be formed by successively depositing a first gate material layer and a first sacrificial material layer on the first gate insulating layer, and patterning the first gate material layer and the first sacrificial material layer. The storage electrode, the second signal line, and the second sacrificial layer may be formed by successively depositing a second gate material layer and a second sacrificial material layer on the second gate insulating layer, and patterning the second gate material layer and the second sacrificial material layer.

In an embodiment, the first sacrificial layer may be patterned with the gate electrode and the first signal line by using a same mask, and the second sacrificial layer may be patterned with the storage electrode and the second signal line by using a same mask.

In an embodiment, the connecting member may include: a first connecting member connected to the first signal line; and a second connecting member connected to the second signal line. The first connection member may extend through the interlayer insulating layer, the second gate insulating layer, and the first sacrificial layer to be connected to the first signal line. The second connection member may extend through the interlayer insulating layer and the second sacrificial layer to be connected to the second signal line.

In an embodiment, a bottom surface of the first connecting member may be in contact with the first signal line, and a side surface of the first connecting member may be surrounded by the interlayer insulating layer, the second gate insulating layer, and the first sacrificial layer; and a bottom surface of the second connecting member may be in contact with the second signal line, and a side surface of the second connecting member may be surrounded by the interlayer insulating layer and the second sacrificial layer.

In an embodiment, the first sacrificial layer and the second sacrificial layer may be formed entirely on the substrate.

In an embodiment, the sacrificial layer may be directly on the second signal line and the storage electrode.

In an embodiment, the signal line may include: a lower signal line including aluminum; and an upper signal line on the lower signal line, and including titanium.

According to one or more embodiments of the present disclosure, a display device and a manufacturing method thereof may be provided, in which it may be possible to prevent or substantially prevent damage to wires and/or the like from occurring in a manufacturing process of the display device.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 illustrates a cross-sectional view of a display device according to an embodiment.

FIG. 2-FIG. 13 illustrate cross-sectional views of sequential processes of a manufacturing method of a display device according to an embodiment.

FIG. 14 and FIG. 15 illustrate some layers of a display device according to a comparative example.

FIG. 16 illustrates some layers of a display device according to an embodiment.

FIG. 17 illustrates a cross-sectional view of a display device according to an embodiment.

FIG. 18 illustrates a cross-sectional view of a display device according to an embodiment.

FIG. 19-FIG. 28 illustrate cross-sectional views of sequential processes of a manufacturing method of a display device according to an embodiment.

FIG. 29 illustrates a cross-sectional view of a display device according to an embodiment.

FIG. 30 illustrates a circuit diagram of a pixel of a display device according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

As used herein, the phrase “in a plan view” may refer to a view of an object portion from above, and the phrase “in a cross-sectional view” may refer to a view of a cross-section of an object from a side taken by vertically cutting the object portion.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

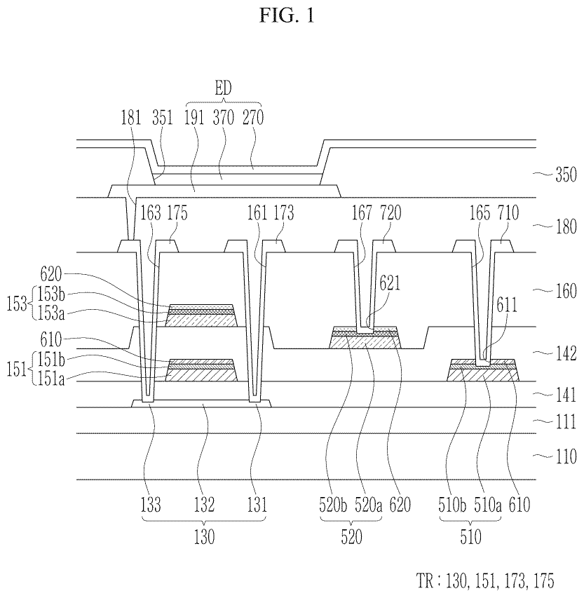

First, a display device according to an embodiment will be described in more detail with reference to FIG. 1.

FIG. 1 illustrates a cross-sectional view of a display device according to an embodiment.

Referring to FIG. 1, a display device according to an embodiment may include a substrate 110, a transistor TR positioned on the substrate 110, and a light emitting diode ED connected to the transistor TR. In addition, a plurality of signal lines may be positioned on the substrate 110. The signal lines may include a first signal line 510, a second signal line 520, and the like. Although not illustrated in the view of FIG. 1, at least one of the signal lines may be connected to the transistor TR to transfer a signal.

The substrate 110 may include at least one of polystyrene, polyvinyl alcohol, poly(methyl methacrylate), polyethersulfone, polyacrylate, polyetherimide, polyethylene naphthalate, polyethylene terephthalate, polyphenylene sulfide, polyarylate, polyimide, polycarbonate, cellulose triacetate, or cellulose acetate propionate. The substrate 110 may be a rigid substrate, or a flexible substrate capable of bending, folding, rolling, or the like. The substrate 110 may be a single layer or multilayers. In the substrate 110, at least one base layer and at least one inorganic layer may be alternately stacked with each other. The at least one base layer may include a polymer resin that is a single layer or a plurality of sequentially stacked layers.

A semiconductor layer including a semiconductor 130 of the transistor TR may be positioned on the substrate 110. The semiconductor 130 may include a first region 131, a channel 132, and a second region 133. The first region 131 and the second region 133 may be positioned at opposite sides of the channel 132 of the semiconductor 130, respectively. The semiconductor layer may include a semiconductor material, such as polysilicon.

A buffer layer 111 may be disposed between the substrate 110 and the semiconductor layer. The buffer layer 111 may have a single or multi-layered structure. The buffer layer 111 may include an inorganic insulating material or organic insulating material, for example, such as silicon nitride (SiNₓ), silicon oxide (SiOₓ), and/or silicon oxynitride (SiOₓN_{y}). The buffer layer 111 may be omitted as needed or desired. In addition, a barrier layer may be further disposed between the substrate 110 and the buffer layer 111. The barrier layer may have a single or multi-layered structure. The barrier layer may include an inorganic insulating material, such as silicon nitride (SiNx), silicon oxide (SiOx), and/or silicon oxynitride (SiOxNy).

A first gate insulating layer 141 may be disposed on the semiconductor layer including the semiconductor 130 of the transistor TR. The first gate insulating layer 141 may have a single or multi-layered structure. The first gate insulating layer 141 may include an inorganic insulating material, such as silicon nitride (SiNx), silicon oxide (SiOx), and/or silicon oxynitride (SiOxNy).

A first gate conductive layer including a gate electrode 151 of the transistor TR may be disposed on the first gate insulating layer 141. In this case, the gate electrode 151 may overlap with the channel 132 of the semiconductor 130. The first gate conductive layer may have a single-layer or multi-layered structure. The first gate conductive layer may include a metal material, such as molybdenum (Mo), aluminum (Al), copper (Cu), and/or titanium (Ti). For example, the first gate conductive layer may be formed to include a double layered structure, and may include a layer including aluminum (Al) and a layer including titanium (Ti). In this case, the gate electrode 151 may include a lower gate electrode 151a and an upper gate electrode 151b. The upper gate electrode 151b may be positioned directly on the lower gate electrode 151a. The lower gate electrode 151a may include aluminum (Al), and the upper gate electrode 151b may include titanium (Ti).

After forming the first gate conductive layer, a doping process or a plasma treatment may be performed. A portion of the semiconductor layer covered by the first gate conductive layer is not subjected to the doping or the plasma treatment, and a portion of the semiconductor layer that is not covered by the first gate conductive layer may be doped or treated with plasma to have the same or substantially the same characteristics as those of a conductor. For example, the channel 132 of the semiconductor 130 may not be doped or plasma treated, and the first region 131 and the second region 133 of the semiconductor 130 may be doped or plasma treated.

The first gate conductive layer may further include a first signal line 510. The first signal line 510 may be positioned at (e.g., in or on) a same layer as that of the gate electrode 151, and may include a same material as that of the gate electrode 151. The first signal line 510 and the gate electrode 151 may be formed by a same or substantially the same process. The first signal line 510 may include a first lower signal line 510a and a first upper signal line 510b. The first upper signal line 510b may be positioned directly on the first lower signal line 510a. The first lower signal line 510a may include aluminum (Al), and the first upper signal line 510b may include titanium (Ti).

A first sacrificial layer 610 may be disposed on the first gate conductive layer. The first sacrificial layer 610 may be disposed on the gate electrode 151 and the first signal line 510. The first sacrificial layer 610 may include an amorphous silicon material.

The first sacrificial layer 610 may be disposed directly on the gate electrode 151, and directly on the first signal line 510. The upper gate electrode 151b may be positioned between the lower gate electrode 151a and the first sacrificial layer 610. The first upper signal line 510b may be positioned between the first lower signal line 510a and the first sacrificial layer 610. The gate electrode 151, the first signal line 510, and the first sacrificial layer 610 may be patterned by using a same mask. Accordingly, the first sacrificial layer 610 may have the same or substantially the same planar shape as those of the gate electrode 151 and the first signal line 510, and may have the same or substantially the same widths as those of the gate electrode 151 and the first signal line 510.

However, in some regions, the first sacrificial layer 610 may have a pattern that is different from that of the first signal line 510. For example, the first sacrificial layer 610 may not be formed on a partial region of the first signal line 510. The first sacrificial layer 610 may have an opening 611, and the first sacrificial layer 610 may be positioned at opposite sides of the opening 611. In other words, the opening 611 may be surrounded (e.g., around a periphery thereof) by the first sacrificial layer 610.

A second gate insulating layer 142 may be disposed on the first sacrificial layer 610. A portion of the second gate insulating layer 142 may be positioned directly on the first gate insulating layer 141. The second gate insulating layer 142 may have a single or multi-layered structure. The second gate insulating layer 142 may include an inorganic insulating material, such as silicon nitride (SiNx), silicon oxide (SiOx), and/or silicon oxynitride (SiOxNy).

A second gate conductive layer including the storage electrode 153 may be disposed on the second gate insulating layer 142. In this case, the storage electrode 153 may overlap with the gate electrode 151 of the transistor TR to form a storage capacitor. The second gate conductive layer may have a single-layer or multi-layered structure. The second gate conductive layer may include a metal material, such as molybdenum (Mo), aluminum (Al), copper (Cu), and/or titanium (Ti). For example, the second gate conductive layer may be formed to include a double layered structure, and may include a layer including aluminum (Al) and a layer including titanium (Ti). In this case, the storage electrode 153 may include a lower storage electrode 153a and an upper storage electrode 153b. The upper storage electrode 153b may be positioned directly on the lower storage electrode 153a. The lower storage electrode 153a may include aluminum (Al), and the upper storage electrode 153b may include titanium (Ti).

The second gate conductive layer may further include a second signal line 520. The second signal line 520 may be positioned at (e.g., in or on) a same layer as that of the storage electrode 153, and may include a same material as that of the storage electrode 153. The second signal line 520 and the storage electrode 153 may be formed by the same or substantially the same process. The second signal line 520 may include a second lower signal line 520a and a second upper signal line 520b. The second upper signal line 520b may be positioned directly on the second lower signal line 520a. The second lower signal line 520a may include aluminum (Al), and the second upper signal line 520b may include titanium (Ti).

A second sacrificial layer 620 may be disposed on the second gate conductive layer. The second sacrificial layer 620 may be disposed on the storage electrode 153 and the second signal line 520. The second sacrificial layer 620 may include an amorphous silicon material. The second sacrificial layer 620 may be made of the same or substantially the same material as that of the first sacrificial layer 610.

The second sacrificial layer 620 may be disposed directly on the storage electrode 153, and directly on the first signal line 520. The upper storage electrode 153b may be positioned between the lower storage electrode 153a and the second sacrificial layer 620. The second upper signal line 520b may be positioned between the second lower signal line 520a and the second sacrificial layer 620. The storage electrode 153, the second signal line 520, and the second sacrificial layer 620 may be patterned by using a same mask. Accordingly, the second sacrificial layer 620 may have the same or substantially the same planar shape as those of the storage electrode 153 and the second signal line 520, and may have the same or substantially the same widths as those of the storage electrode 153 and the second signal line 520.

However, in some regions, the second sacrificial layer 620 may have a pattern that is different from that of the second signal line 520. For example, the second sacrificial layer 620 may not be formed on a partial region of the second signal line 520. The second sacrificial layer 620 may have an opening 621, and the second sacrificial layer 620 may be positioned at opposite sides of the opening 621. In other words, the opening 621 may be surrounded (e.g., around a periphery thereof) by the second sacrificial layer 620.

An interlayer insulating layer 160 may be disposed on the second sacrificial layer 620. A portion of the interlayer insulating layer 160 may be positioned directly on the second gate insulating layer 142. The interlayer insulating layer 160 may have a single-layer or multi-layered structure. The interlayer insulating layer 160 may include an inorganic insulating material, such as silicon nitride (SiNx), silicon oxide (SiOx), and/or silicon oxynitride (SiOxNy).

A first data conductive layer including the source electrode 173 and the drain electrode 175 of the transistor TR may be disposed on the interlayer insulating layer 160. The first data conductive layer may have a single-layer or multi-layered structure. The first data conductive layer may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and/or the like. The first data conductive layer may have a triple-layered structure of a lower film containing a refractory metal, such as molybdenum, chromium, tantalum, titanium, or an alloy thereof, an intermediate film containing an aluminum-based metal, a silver-based metal, or a copper-based metal having low resistivity, and an upper film containing a refractory metal, such as molybdenum, chromium, tantalum, or titanium.

The interlayer insulating layer 160, the second gate insulating layer 142, and the first gate insulating layer 141 may each have an opening 161 overlapping with the source electrode 173 of the transistor TR and the first region 131 of the semiconductor 130. The source electrode 173 of the transistor TR may be connected to the first region 131 of the semiconductor 130 through the opening 161. In addition, the interlayer insulating layer 160, the second gate insulating layer 142, and the first gate insulating layer 141 may each have an opening 163 overlapping with the drain electrode 175 of the transistor TR and the second region 133 of the semiconductor 130. The drain electrode 175 of the transistor TR may be connected to the second region 133 of the semiconductor 130 through the opening 163. Accordingly, the semiconductor 130, the gate electrode 151, the source electrode 173, and the drain electrode 175 may constitute the transistor TR. According to an embodiment, the transistor TR may include the first region 131 and the second region 133 of the semiconductor 130, and may not include the source electrode 173 and/or the drain electrode 175.

The first data conductive layer may further include a first connecting member 710 and a second connecting member 720. The first connecting member 710 and the second connecting member 720 may be positioned at (e.g., in or on) a same layer as that of the source electrode 173 and the drain electrode 175, and may include a same material as that of the source electrode 173 and the drain electrode 175. The first connecting member 710 and the second connecting member 720 may be formed by the same or substantially the same process as that of the source electrode 173 and the drain electrode 175.

The first connecting member 710 may overlap with the first signal line 510. The interlayer insulating layer 160 and the second gate insulating layer 142 may have an opening 165 overlapping with the first connecting member 710 and the first signal line 510. The first connecting member 710 may be connected to the first signal line 510 through the opening 165. An opening formed in (e.g., penetrating) the first sacrificial layer 610 may overlap with the opening 165 of the interlayer insulating layer 160 and the second gate insulating layer 142. Accordingly, the first connecting member 710 may be connected to the first signal line 510 through the first sacrificial layer 610. A bottom surface of the first connecting member 710 may be in contact with the first upper signal line 510b. A thickness of the portion of the first upper signal line 510b that is in contact with the first connecting member 710 may be relatively thinner than a thickness of the portion of the first upper signal line 510b that does not contact the first connecting member 710. A side surface of the first connecting member 710 may be surrounded (e.g., around a periphery thereof) by the first sacrificial layer 610, the second gate insulating layer 142, and the interlayer insulating layer 160.

The second connecting member 720 may overlap with the second signal line 520. The interlayer insulating layer 160 may have an opening 167 overlapping with the second connecting member 720 and the second signal line 520. The second connecting member 720 may be connected to the first signal line 520 through the opening 167. An opening formed in (e.g., penetrating) the second sacrificial layer 620 may overlap with the opening 167 of the interlayer insulating layer 160. Accordingly, the second connecting member 720 may be connected to the second signal line 520 through the second sacrificial layer 620. A bottom surface of the second connecting member 720 may be in contact with the second upper signal line 520b. A thickness of the portion of the second upper signal line 520b that is in contact with the second connecting member 720 may be relatively thinner than a thickness of the portion of the second upper signal line 520b that does not contact the second connecting member 720. A side surface of the second connecting member 720 may be surrounded (e.g., around a periphery thereof) by the second sacrificial layer 620 and the interlayer insulating layer 160.

A passivation layer 180 may be disposed on the first data conductive layer including the source electrode 173, the drain electrode 175, the first connecting member 710, and the second connecting member 720. The passivation layer 180 may include a general purpose polymer, such as poly(methyl methacrylate) (PMMA) or polystyrene (PS), a polymer derivative having a phenolic group, an organic insulating material, such as an acrylic polymer, an imide polymer, a polyimide, an acrylic polymer, a siloxane polymer, and/or the like

In some embodiments, a second data conductive layer may be further formed on the passivation layer 180. The transistor TR and the light emitting diode ED may be connected to each other through a bridge electrode or the like positioned at (e.g., in or on) the second data conductive layer. In addition, some of the signal lines may be positioned at (e.g., in or on) the second data conductive layer.

The light emitting diode ED may be positioned on the passivation layer 180. The light emitting diode ED may be connected to the transistor TR. The light emitting diode ED may include a first electrode 191, an emission layer 370, and a second electrode 270.

The first electrode 191 may be positioned on the passivation layer 180. The first electrode 191 may also be referred to as an anode, and may be formed as a single layer including a transparent conductive oxide or a metal material, or may be formed as multiple layers including one or more transparent conductive oxides and/or one or more metal materials. The transparent conductive oxide may include an indium tin oxide (ITO), a poly-ITO, an indium zinc oxide (IZO), an indium gallium zinc oxide (IGZO), an indium tin zinc oxide (ITZO), and/or the like. The metal material may include silver (Ag), molybdenum (Mo), copper (Cu), gold (Au), and/or aluminum (Al). For example, the first electrode 191 may include a lower layer, an intermediate layer, and an upper layer. The lower layer of the first electrode 191 may be disposed directly on the passivation layer 180, the intermediate layer may be disposed on the lower layer, and the upper layer may be disposed on the intermediate layer. In this case, the intermediate layer of the first electrode 191 may include (e.g., may be made of) a material that is different from that of the lower layer and the upper layer. For example, the intermediate layer may include (e.g., may be made of) silver (Ag), and the lower layer and the upper layer may include (e.g., may be made of) an ITO.

The passivation layer 180 may have an opening 181 overlapping with the first electrode 191 and the drain electrode 175. The first electrode 191 may be connected to the drain electrode 175 through the opening 181. Accordingly, the first electrode 191 may be connected to the transistor TR.

A partition wall 350 may be disposed on the first electrode 191. The partition wall 350 may also be referred to as a pixel defining layer PDL, and has a pixel opening 351 overlapping with at least a portion of the first electrode 191. In this case, the pixel opening 351 may overlap with a central portion of the first electrode 191, and may not overlap with an edge portion of the first electrode 191. As a result, a size of the pixel opening 351 may be smaller than that of the first electrode 191. The partition wall 350 may be formed as an organic insulator including at least one material of a polyimide, a polyamide, an acryl resin, benzocyclobutene, or a phenol resin. As another example, the partition wall 350 may include an inorganic insulating material, such as silicon nitride (SiNx), silicon oxide (SiOx), and/or silicon oxynitride (SiOxNy). As another example, the partition wall 350 may be formed of a black pixel defining layer BPDL including a light-blocking material. In this case, the light-blocking material may include carbon black, carbon nanotubes, a resin or paste containing a black dye, metal particles, such as nickel, aluminum, molybdenum, and/or suitable alloys thereof, metal oxide particles (e.g., chromium oxide) or metal nitride particles (e.g., chromium nitride), and/or the like. When the partition wall 350 includes a light-blocking material, reflection of external light by metal structures positioned under (e.g., underneath) the partition wall 350 may be reduced. However, the present disclosure is not limited thereto, and the partition wall 350 may not include a light-blocking material, and may include a light-transmitting organic insulating material.

The emission layer 370 may be disposed in the pixel opening 351 of the partition wall 350. The emission layer 370 may overlap with the first electrode 191. The emission layer 370 may include an organic material that emits light, such as red, green, or blue light. The emission layer 370 may include a low molecular weight organic material or a high molecular weight organic material. Although the emission layer 370 is illustrated as a single layer, in some embodiments, an auxiliary layer, such as a hole injection layer (HIL), a hole transporting layer (HTL), an electron transporting layer (ETL), and/or an electron injection layer (EIL), may be further positioned at upper and/or lower sides of the emission layer 370. In this case, a hole injection layer and/or a hole transport layer may be positioned under (e.g., underneath) the emission layer 370, and an electron transport layer and/or an electron injection layer may be positioned above the emission layer 370.

The second electrode 270 may be positioned on the emission layer 370 and the partition wall 350. The second electrode 270 may be entirely positioned in most regions on the substrate 110. The second electrode 270 may also be referred to as a cathode electrode, and may include a reflective metal including calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), calcium (Ca), and/or the like, or a transparent conductive oxide (TCO), such as indium tin oxide (ITO) or indium zinc oxide (IZO).

The first electrode 191, the emission layer 370, and the second electrode 270 may constitute the light emitting diode ED. In this case, the first electrode 191 may be an anode electrode that is a hole injection electrode, and the second electrode 270 may be a cathode electrode that is an electron injection electrode. However, the present disclosure is not limited thereto, and the anode and the cathode may be reversed with each other, depending on a driving method of the display device.

When holes and electrons are injected from the first electrode 191 and the second electrode 270 into the emission layer 370, excitons formed by combining the injected holes and electrons with each other are emitted when they fall from an excited state to a ground state.

An encapsulation layer may be further disposed on the second electrode 270. The encapsulation layer may protect the light emitting diode ED from moisture and/or oxygen that may be introduced from the outside, and may include at least one inorganic layer and at least one organic layer. For example, the encapsulation layer may have a structure in which a first inorganic encapsulation layer, an organic encapsulation layer, and a second inorganic encapsulation layer are stacked on one another. However, the present disclosure is not limited thereto, and numbers of inorganic and organic layers constituting the encapsulation layer may be variously modified as needed or desired.

A display device according to an embodiment may include a plurality of pixels, and each of the pixels may include a plurality of transistors, and a light emitting diode connected to the transistors. Although a structure in which the light emitting diode is connected to one transistor is illustrated in the figure, a plurality of transistors may be positioned in one pixel. For example, one pixel may include two transistors, and a light emitting diode connected to the transistors.

In addition, although a structure including the polycrystalline transistor has been described above, the present disclosure is not limited thereto. Some of the transistors included in one pixel may be formed as a polycrystalline transistor, and others may be formed as an oxide transistor. In this case, an oxide semiconductor layer, a third gate conductive layer, and the like constituting the oxide transistor may be further formed.

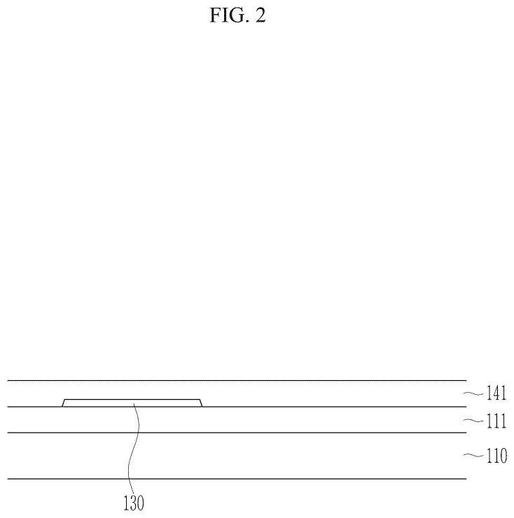

Next, a method of manufacturing a display device according to an embodiment will be described in more detail with reference to FIGS. 2 through 13.

FIG. 2 through FIG. 13 illustrate cross-sectional views of sequential processes of a manufacturing method of a display device according to an embodiment. Referring to FIG. 2, a buffer layer 111 is formed on the substrate 110 by using an inorganic insulating material, such as silicon nitride (SiNx), silicon oxide (SiOx), or silicon oxynitride (SiOxNy), or an organic insulating material. The buffer layer 111 may be formed entirely on the substrate 110.

A semiconductor layer including the semiconductor 130 is formed on the buffer layer 111 by using a polycrystalline semiconductor material. The semiconductor 130 is formed by patterning the polycrystalline semiconductor material layer using a mask (e.g., a predetermined mask).

A first gate insulating layer 141 is formed on the semiconductor layer including the semiconductor 130 by using an inorganic insulating material, such as silicon nitride (SiNx), silicon oxide (SiOx), or silicon oxynitride (SiOxNy).

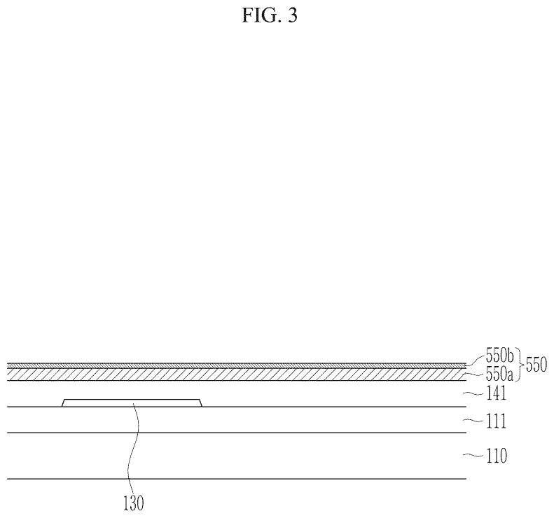

Referring to FIG. 3, a first gate material layer 550 is formed on the first gate insulating layer 141. The first gate material layers 550 may have a single-layer or multi-layered structure. The first gate material layer 550 may include a first lower gate material layer 550a and a first upper gate material layer 550b. The first lower gate material layer 550a and the first upper gate material layer 550b may be successively deposited. Accordingly, the first upper gate material layer 550b is positioned directly on the first lower gate material layer 550a. The first gate material layer 550 may include a metal material, such as molybdenum (Mo), aluminum (Al), copper (Cu), and/or titanium (Ti). For example, the first lower gate material layer 550a may be formed using aluminum (Al), and the first upper gate material layer 550b may be formed using titanium (Ti).

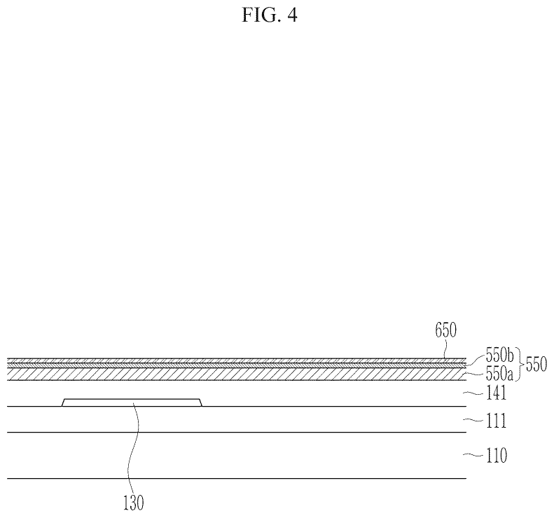

Referring to FIG. 4, a first sacrificial material layer 650 is formed on the first gate material layer 550 by using an amorphous silicon material. The first lower gate material layer 550a, the first upper gate material layer 550b, and the first sacrificial material layer 650 may be sequentially and successively deposited.

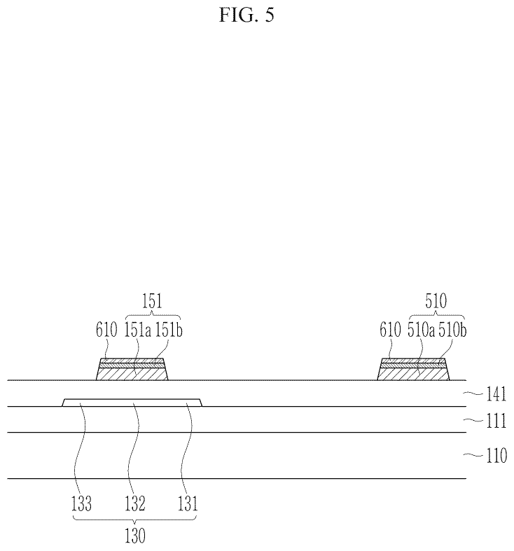

Referring to FIG. 5, the first sacrificial material layer 650, the first upper gate material layer 550b, and the first lower gate material layer 550a are patterned using a photo and etching process to form the gate electrode 151, the first signal line 510, and the first sacrificial layer 610. The gate electrode 151, the first signal line 510, and the first sacrificial layer 610 may be formed in a same process with each other using a same mask. The first sacrificial layer 610 may be disposed on the gate electrode 151 and the first signal line 510. The first sacrificial layer 610 may have the same or substantially the same planar shapes as those of the gate electrode 151 and the first signal line 510, and may have the same or substantially the same widths as those of the gate electrode 151 and the first signal line 510.

The gate electrode 151 may overlap with the semiconductor 130, and the first signal line 510 may be spaced apart from the gate electrode 151. The gate electrode 151 may include a lower gate electrode 151a and an upper gate electrode 151b. The upper gate electrode 151b may be positioned directly on the lower gate electrode 151a. The first sacrificial layer 610 may be disposed directly on the upper gate electrode 151b. The upper gate electrode 151b may be positioned between the lower gate electrode 151a and the first sacrificial layer 610. The first signal line 510 may include a first lower signal line 510a and a first upper signal line 510b. The first upper signal line 510b may be positioned directly on the first lower signal line 510a. The first sacrificial layer 610 may be disposed directly on the first upper signal line 510b. The first upper signal line 510b may be positioned between the first lower signal line 510a and the first sacrificial layer 610.

Subsequently, a doping process or a plasma treatment may be performed. A portion of the semiconductor 130 covered by the gate electrode 151 may be formed as the channel 132 without being doped or plasma-treated. Portions of the semiconductor 130 not covered by the gate electrode 151 may be doped or subjected to plasma treatment to have the same or substantially the same characteristics as those of a conductor, and may be formed as the first region 131 and the second region 133. The first region 131 and the second region 133 of the semiconductor 130 may be positioned at opposite sides of the channel 132.

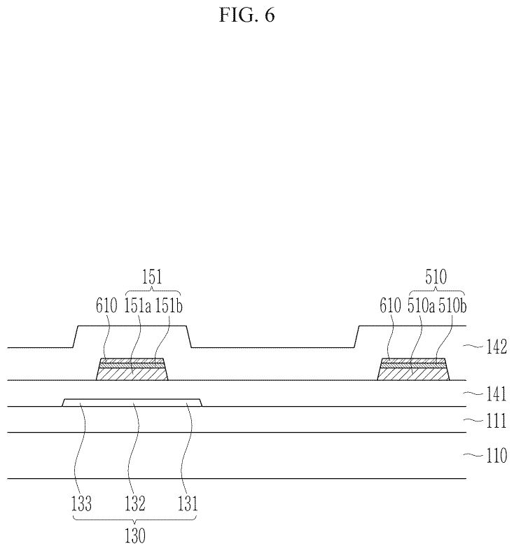

Referring to FIG. 6, a second gate insulating layer 142 is formed on the first sacrificial layer 610 by using an inorganic insulating material, such as silicon nitride (SiNx), silicon oxide (SiOx), or silicon oxynitride (SiOxNy). At least a portion of the second gate insulating layer 142 may be positioned directly on the first gate insulating layer 141. The second gate insulating layer 142 may be entirely formed on the substrate 110. The second gate insulating layer 142 may cover an upper surface of the first sacrificial layer 610, and may cover side surfaces of the first sacrificial layer 610, the gate electrode 151, and the first signal line 510.

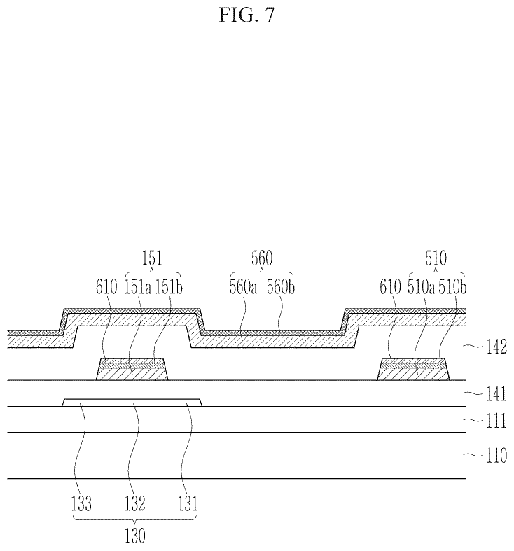

Referring to FIG. 7, a second gate material layer 560 is formed on the second gate insulating layer 142. The second gate material layer 560 may have a single-layer or multi-layered structure. The second gate material layer 560 may include a second lower gate material layer 560a and a second upper gate material layer 560b. The second lower gate material layer 560a and the second upper gate material layer 560b may be successively deposited. The second gate material layer 560 may include a metal material. such as molybdenum (Mo), aluminum (Al), copper (Cu), and/or titanium (Ti). For example, the second lower gate material layer 560a may be formed using aluminum (Al), and the second upper gate material layer 560b may be formed using titanium (Ti).

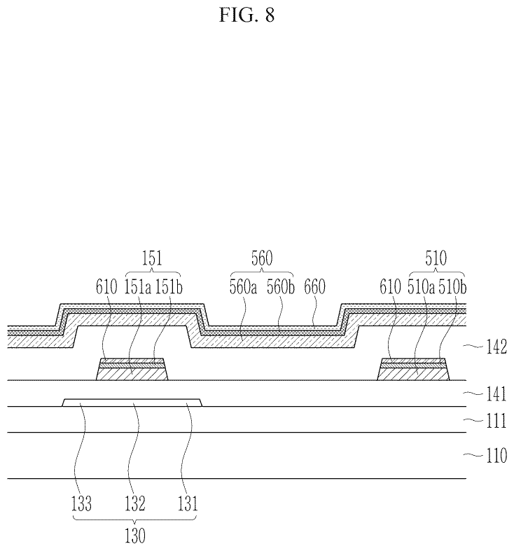

Referring to FIG. 8, a second sacrificial material layer 660 is formed on the second gate material layer 560 by using an amorphous silicon material. The second lower gate material layer 560a, the second upper gate material layer 560b, and the second sacrificial material layer 660 may be sequentially and successively deposited.

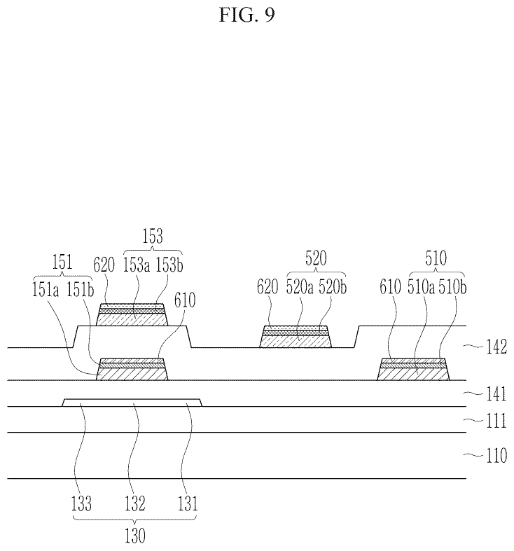

Referring to FIG. 9, the second sacrificial material layer 660, the second upper gate material layer 560b, and the second lower gate material layer 560a are patterned using a photo and etching process to form the storage electrode 153, the second signal line 520, and the second sacrificial layer 620. The storage electrode 153, the second signal line 520, and the second sacrificial layer 620 may be formed in the same or substantially the same process with each other using a same mask. The second sacrificial layer 620 may be disposed on the storage electrode 153 and the second signal line 520. The second sacrificial layer 620 may have the same or substantially the same planar shapes as those of the storage electrode 153 and the second signal line 520, and may have the same or substantially the same widths as those of the storage electrode 153 and the second signal line 520.

The storage electrode 153 may overlap with the gate electrode 151, and the second signal line 520 may be spaced apart from the storage electrode 153. The storage electrode 153 may include a lower storage electrode 153a and an upper storage electrode 153b. The upper gate electrode 153b may be positioned directly on the lower gate electrode 153a. The second sacrificial layer 620 may be disposed directly on the upper storage electrode 153b. The upper storage electrode 153b may be positioned between the lower storage electrode 153a and the second sacrificial layer 620. The second signal line 520 may include a second lower signal line 520a and a second upper signal line 520b. The second upper signal line 520b may be positioned directly on the second lower signal line 520a. The second sacrificial layer 620 may be disposed directly on the second upper signal line 520b. The second upper signal line 520b may be positioned between the second lower signal line 520a and the second sacrificial layer 620.

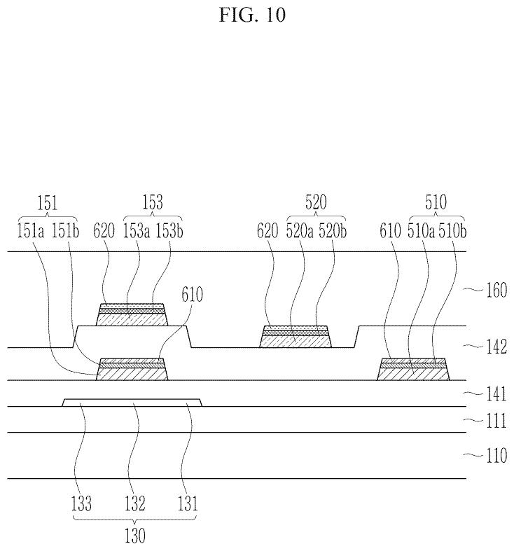

Referring to FIG. 10, an interlayer insulating layer 160 is formed on the second sacrificial layer 620 by using an inorganic insulating material, such as silicon nitride (SiNx), silicon oxide (SiOx), or silicon oxynitride (SiOxNy). At least a portion of the interlayer insulating layer 160 may be positioned directly on the second gate insulating layer 142. The interlayer insulating layer 160 may be entirely formed on the substrate 110. The interlayer insulating layer 160 may cover an upper surface of the second sacrificial layer 620, and may cover side surfaces of the second sacrificial layer 620, the storage electrode 153, and the second signal line 520.

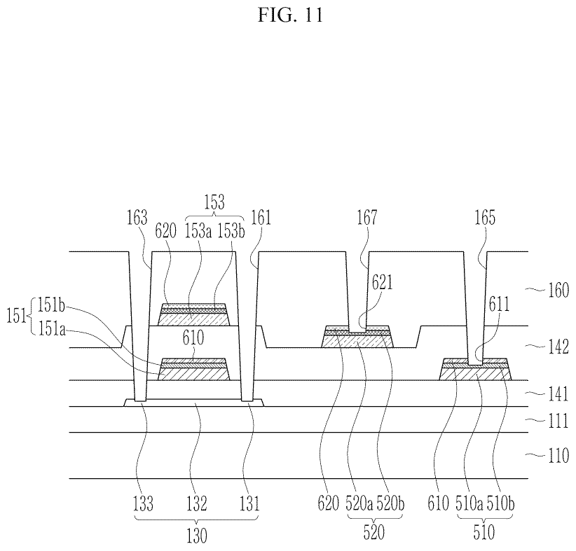

Referring to FIG. 11, the interlayer insulating layer 160, the second gate insulating layer 142, and the first gate insulating layer 141 are patterned using a photo and etching process, to form openings 161, 163, 165, and 167. The openings 161, 163, 165, and 167 may include the opening 161 overlapping with the first region 131 of the semiconductor 130, the opening 163 overlapping with the second region 133 of the semiconductor 130, the opening 165 overlapping with the first signal line 510, and the opening 167 overlapping with the second signal line 520.

The opening 161 overlapping with the first region 131 of the semiconductor 130 may be formed in (e.g., may penetrate) the interlayer insulating layer 160, the second gate insulating layer 142, and the first gate insulating layer 141. The first region 131 of the semiconductor 130 may be exposed by the opening 161.

The opening 163 overlapping with the second region 133 of the semiconductor 130 may be formed in (e.g., may penetrate) the interlayer insulating layer 160, the second gate insulating layer 142, and the first gate insulating layer 141. The second region 133 of the semiconductor 130 may be exposed by the opening 163.

The opening 165 overlapping with the first signal line 510 may be formed in (e.g., may penetrate) the interlayer insulating layer 160 and the second gate insulating layer 142. The opening 165 may also overlap with the first sacrificial layer 610. The first sacrificial layer 610 is positioned at a relatively upper layer compared to the semiconductor 130. Accordingly, an upper surface of the first sacrificial layer 610 may be exposed before an upper surface of the semiconductor 130 is exposed in the process of forming the openings 161, 163, 165, and 167. Therefore, at least a portion of the first sacrificial layer 610 may be etched together in a process of etching the interlayer insulating layer 160, the second gate insulating layer 142, and the first gate insulating layer 141. In other words, the opening 611 may also be formed in the first sacrificial layer 610, and the opening 611 of the first sacrificial layer 610 may overlap with the opening 165 formed in the interlayer insulating layer 160 and the second gate insulating layer 142. The opening 611 of the first sacrificial layer 610 may have the same or substantially the same planar shape as that of the opening 165 formed in the interlayer insulating layer 160 and the second gate insulating layer 142.

When the opening 611 is formed in the first sacrificial layer 610, an upper surface of the first signal line 510 positioned under the first sacrificial layer 610 may be exposed. In this case, the upper surface of the first upper signal line 510b may be exposed. In some embodiments, the first upper signal line 510b may be etched, and a portion of the first upper signal line 510b overlapping with the opening 611 of the first sacrificial layer 610 may have a thinner thickness. A thickness of the portion of the first signal line 510 overlapping with the opening 611 may be thinner than a thickness of the portion of the first signal line 510 not overlapping with the opening 611. In other words, a groove may be formed in the first signal line 510.

The opening 167 overlapping with the second signal line 520 may be formed in (e.g., may penetrate) the interlayer insulating layer 160. The opening 167 may also overlap with the second sacrificial layer 620. The second sacrificial layer 620 is positioned at a relatively upper layer compared to the semiconductor 130. Accordingly, an upper surface of the second sacrificial layer 620 may be exposed before an upper surface of the semiconductor 130 is exposed in the process of forming the openings 161, 163, 165, and 167. Therefore, at least a portion of the second sacrificial layer 620 may be etched together in a process of etching the interlayer insulating layer 160, the second gate insulating layer 142, and the first gate insulating layer 141. In other words, the opening 621 may also be formed in the second sacrificial layer 620, and the opening 621 of the second sacrificial layer 620 may overlap with the opening 167 formed in the interlayer insulating layer 160. The opening 621 of the second sacrificial layer 620 may have the same or substantially the same planar shape as that of the opening 167 formed in the interlayer insulating layer 160.

When the opening 621 is formed in the second sacrificial layer 620, an upper surface of the second signal line 520 positioned under the second sacrificial layer 620 may be exposed. In this case, an upper surface of the second upper signal line 520b may be exposed. In some embodiments, the second upper signal line 520b may be etched, and a portion of the second upper signal line 520b overlapping with the opening 621 of the second sacrificial layer 620 may have a thinner thickness. A thickness of the portion of the second signal line 520 overlapping with the opening 621 may be thinner than a thickness of the portion of the second signal line 520 not overlapping with the opening 621. In other words, a groove may be formed in the second signal line 520.

After the openings 161, 163, 165, and 167 are formed, an annealing process may be performed. When heat is applied for a suitable time (e.g., a predetermined time), a hydrogen content in the channel 132 of the semiconductor 130 may be lowered. An oxide layer may be formed on the exposed portion of the semiconductor 130 during the annealing process. In other words, upper surfaces of the first region 131 and the second region 133 of the semiconductor 130 exposed by the openings 161 and 163 may be oxidized. A buffered oxide etch (BOE) cleaning process may be performed in order to remove the oxide layer. A process of etching the oxide layer formed on the semiconductor 130 may be performed by supplying a suitable etchant (e.g., a predetermined etchant). At least portions of the first signal line 510 and the second signal line 520 exposed in the cleaning process may be etched together.

In a method of manufacturing a display device according to an embodiment, the first sacrificial layer 610 is disposed on the first signal line 510, and the second sacrificial layer 620 is disposed on the second signal line 520. Accordingly, the first sacrificial layer 610 and the second sacrificial layer 620 may be etched, and damage to the first signal line 510 and the second signal line 520 may be minimized or reduced in a process of forming the openings 161, 163, 165, and 167. A thickness of the first upper signal line 510b and the second upper signal line 520b may be reduced, but the upper surfaces of the first lower signal line 510a and the second lower signal line 520a may not be exposed. Accordingly, the first lower signal line 510a and the second lower signal line 520a may be protected by the first upper signal line 510b and the second upper signal line 520b during the cleaning process. Thus, it may be possible to prevent or substantially prevent the first lower signal line 510a and the second lower signal line 520a from being damaged by the etchant in the cleaning process.

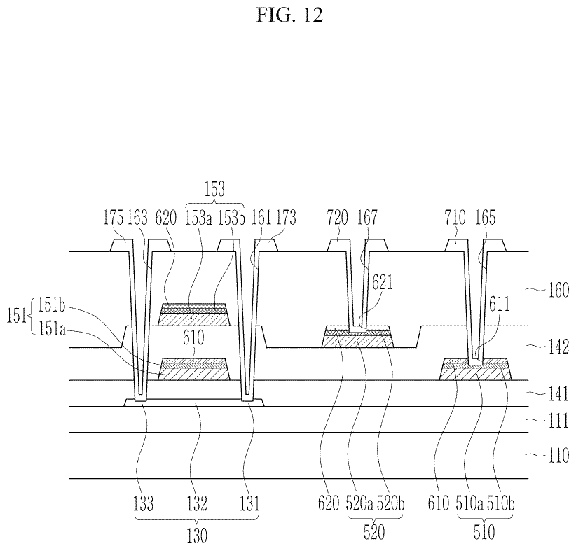

Referring to FIG. 12, a source electrode 173, a drain electrode 175, a first connecting member 710, and a second connecting member 720 are formed by depositing a metal material, and performing a photo and etching process.

The source electrode 173 may be connected to the first region 131 of the semiconductor 130 through the opening 161, and the drain electrode 175 may be connected to the second region 133 of the semiconductor 130 through the opening 163.

The first connecting member 710 may be connected to the first signal line 510 through the opening 165. The first connecting member 710 may be connected to the first upper signal line 510b. A bottom surface of the first connecting member 710 may be in contact with the first upper signal line 510b. However, the present disclosure is not limited thereto, and the first connecting member 710 may be connected to the first lower signal line 510a. A side surface of the first connecting member 710 may be surrounded (e.g., around a periphery thereof) by the first sacrificial layer 610, the second gate insulating layer 142, and the interlayer insulating layer 160.

The second connecting member 720 may be connected to the first signal line 520 through the opening 167. The second connecting member 720 may be connected to the second upper signal line 520b. A bottom surface of the second connecting member 720 may be in contact with the second upper signal line 520b. However, the present disclosure is not limited thereto, and the second connecting member 720 may be connected to the second lower signal line 520a. A side surface of the second connecting member 720 may be surrounded (e.g., around a periphery thereof) by the second sacrificial layer 620 and the interlayer insulating layer 160.

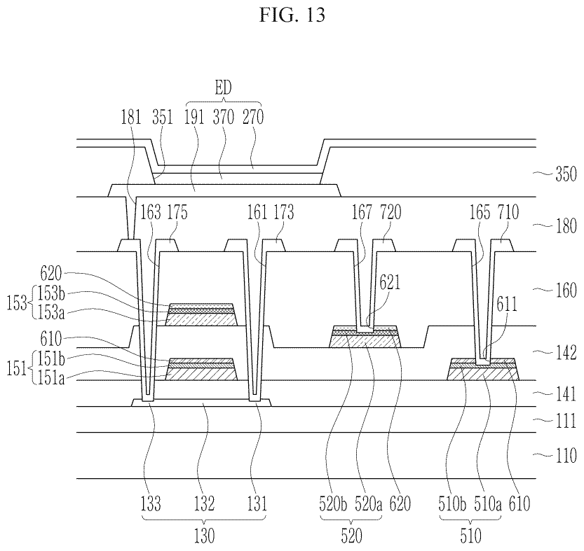

Referring to FIG. 13, a passivation layer 180 is formed on the source electrode 173, the drain electrode 175, the first connecting member 710, and the second connecting member 720. An opening 181 is formed by patterning the passivation layer 180, and a first electrode 191 is formed on the passivation layer 180. The first electrode 191 may be connected to the drain electrode 175 through the opening 181.

The partition wall 350 is formed on the first electrode 191 and the passivation layer 180. A pixel opening 351 is formed by patterning the partition wall 350, and an emission layer 370 is formed in the pixel opening 351. The emission layer 370 may be positioned on the first electrode 191.

A second electrode 270 is formed on the emission layer 370 and the partition wall 350. The first electrode 191, the emission layer 370, and the second electrode 270 may constitute the light emitting diode ED.

In some embodiments, an encapsulation layer may be disposed on the second electrode 270.

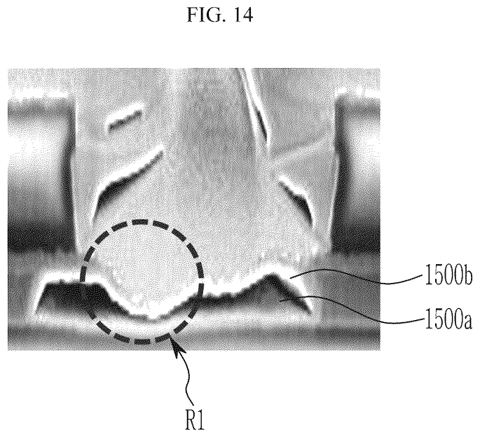

Next, a display device according to an embodiment and a display device according to a comparative example will be compared and described in more detail with reference to FIG. 14 through FIG. 16.

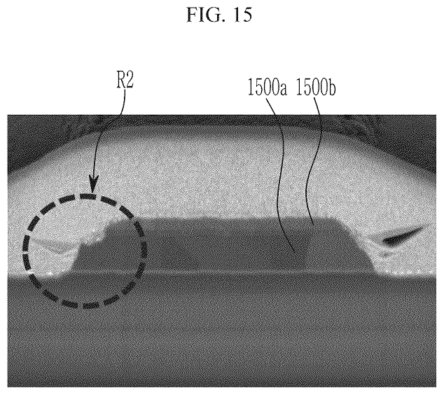

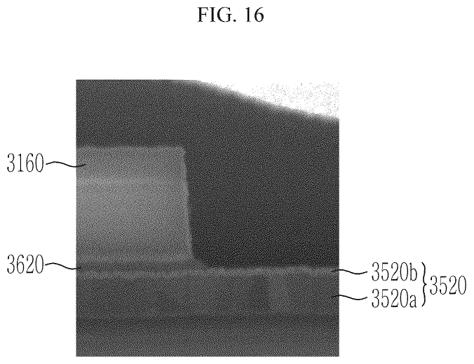

FIG. 14 and FIG. 15 illustrate some layers of a display device according to a comparative example. FIG. 16 illustrates some layers of a display device according to an embodiment.

Referring to FIG. 14, the display device according to the comparative example includes a lower signal line 1500a and an upper signal line 1500b. A separate sacrificial layer is not formed on the upper signal line 1500b. In this case, the lower signal line 1500a may be made of aluminum (Al), and the upper signal line 1500b may be made of titanium (Ti). When the lower signal line 1500a and the upper signal line 1500b are formed, an interlayer insulating layer is formed, and then an etching process is performed to form an opening, such that the upper signal line 1500b may be etched together, and the lower signal line 1500a may be exposed. Thereafter, when a buffered oxide etch (BOE) cleaning process is performed, the lower signal line 1500a may be damaged in an area indicated by R1, as shown in FIG. 14.

Referring to FIG. 15, the display device according to the comparative example includes a lower signal line 1500a and an upper signal line 1500b. A separate sacrificial layer is not formed on the upper signal line 1500b. In this case, the lower signal line 1500a may be made of aluminum (Al), and the upper signal line 1500b may be made of titanium (Ti). When the upper signal line 1500b is formed to be thicker, it may be possible to prevent the lower signal line 1500a from being exposed in the process of forming the opening. However, a surface roughness of the lower signal line 1500a may increase in an etching process for forming the upper signal line 1500b and the lower signal line 1500a, and in a process of etching the thicker upper signal line 1500b made of titanium (Ti). For example, as shown in FIG. 15, a surface of the lower signal line 1500a may be roughly formed in the area indicated by R2.

Referring to FIG. 16, the display device according to an embodiment includes a signal line 3520, and a sacrificial layer 3620 positioned on the signal line 3520. The signal line 3520 may include a lower signal line 3520a and an upper signal line 3520b. In this case, the lower signal line 3520a may include (e.g., may be made of) aluminum (Al), and the upper signal line 3520b may include (e.g., may be made of) titanium (Ti). The sacrificial layer 3620 may be etched during the etching process for forming the opening after the lower signal line 3520a and the upper signal line 3520b are formed, and an interlayer insulating layer 3160 is formed. When all sacrificial layers 3620 are etched, the upper signal line 3520b may be exposed, but the lower signal line 3520a may not be exposed. Thereafter, the lower signal line 3520a is not exposed during the buffered oxide etch cleaning process, and thus, it may be possible to prevent or substantially prevent the lower signal line 3520a from being damaged by the etchant.

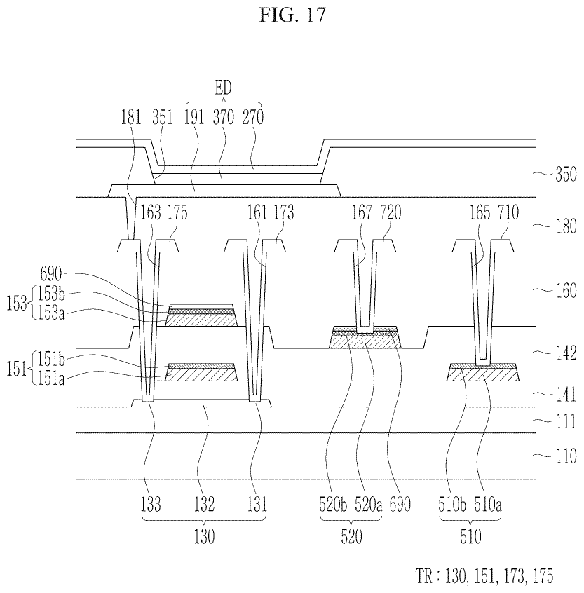

Next, a display device according to an embodiment will be described in more detail with reference to FIG. 17.

FIG. 17 illustrates a cross-sectional view of a display device according to an embodiment.

The display device illustrated in FIG. 17 may be the same or substantially the same as the display device described above with reference to FIG. 1, and thus, the differences are mainly described in more detail, and redundant description of the same or substantially the same components therebetween may not be repeated. The present embodiment may be different from the embodiments described above, in that the first sacrificial layer may be omitted, which will be further described in more detail below.

Referring to FIG. 17, a display device according to an embodiment may include a substrate 110, a transistor TR positioned on the substrate 110, and a light emitting diode ED connected to the transistor TR. In addition, a plurality of signal lines may be positioned on the substrate 110. The signal lines may include a first signal line 510, a second signal line 520, and the like.

In the embodiments described above, the first sacrificial layer 610 may be disposed on the first signal line 510 and the second sacrificial layer 620 may be disposed on the second signal line 520. In the present embodiment, a separate sacrificial layer may not be disposed on the first signal line 510, and a sacrificial layer 690 may be disposed on the second signal line 520. However, the present disclosure is not limited thereto, and a separate sacrificial layer may not be disposed on the second signal line 520, but a sacrificial layer may be disposed on the first signal line 510.

The sacrificial layer 690 may be disposed on the storage electrode 153 and the second signal line 520. The sacrificial layer 690 may include an amorphous silicon material. The sacrificial layer 690 may be concurrently (e.g., simultaneously or substantially simultaneously) patterned with the storage electrode 153 and the second signal line 520 by using a same mask. The sacrificial layer 690 may have the same or substantially the same planar shapes as those of the storage electrode 153 and the second signal line 520.

The sacrificial layer 690 may be etched, and damage to the second signal line 520 may be minimized or reduced in a process of forming the openings 161, 163, 165, and 167 in the interlayer insulating film 160 and the like. A thickness of the second upper signal line 520b may be reduced, but an upper surface of the second lower signal line 520a may not be exposed. Accordingly, during the cleaning process, the second lower signal line 520a may be protected by the second upper signal line 520b, and damage to the second lower signal line 520a by the etchant may be prevented or substantially prevented.

The first signal line 510 is located at (e.g., in or on) a lower layer relative to that of the second signal line 520, and thus, the first signal line 510 may be less prone to being damaged in the process of forming the openings 161, 163, 165, and 167 in the interlayer insulating layer 160 and the like, even when there is no separate sacrificial layer formed thereon.

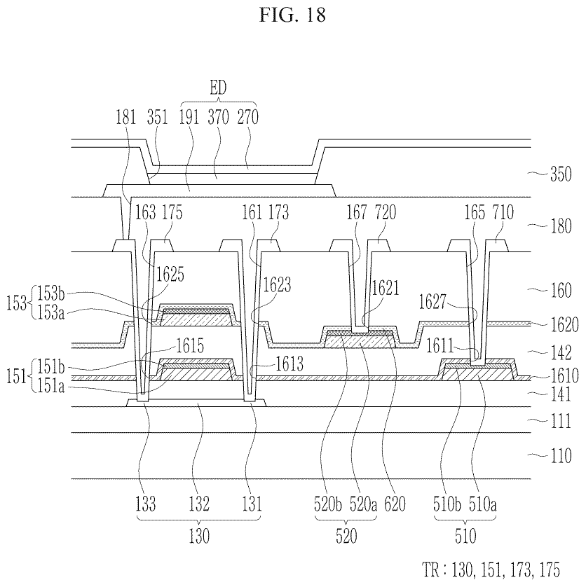

Next, a display device according to an embodiment will be described in more detail with reference to FIG. 18.

FIG. 18 illustrates a cross-sectional view of a display device according to an embodiment.

The display device illustrated in FIG. 18 may be the same or substantially the same as the display device described above with reference to FIG. 1, and thus, the differences are mainly described in more detail, and redundant description of the same or substantially the same components therebetween may not be repeated. The present embodiment may be different from the embodiments described above, in that the first sacrificial layer and the second sacrificial layer may be entirely formed, which will be further described in more detail below.

Referring to FIG. 18, a display device according to an embodiment may include a substrate 110, a transistor TR positioned on the substrate 110, and a light emitting diode ED connected to the transistor TR. In addition, a plurality of signal lines may be positioned on the substrate 110. The signal lines may include a first signal line 510, a second signal line 520, and the like.

A first sacrificial layer 1610 may be disposed on the gate electrode 151 of the transistor TR and the first signal line 510. The first sacrificial layer 1610 may include an amorphous silicon material. In the embodiments described above, the first sacrificial layer 610 may be disposed on the first gate conductive layer, but in the present embodiment, the first sacrificial layer 1610 may be disposed on the entirety or substantially on the entirety of the substrate 110. The first sacrificial layer 1610 may cover an upper surface and a side surface of the gate electrode 151. The first sacrificial layer 1610 may be in contact with an upper surface of the upper gate electrode 151b, and may be in contact with side surfaces of the upper gate electrode 151b and the lower gate electrode 151a. The first sacrificial layer 1610 may cover an upper surface and a side surface of the first signal line 510. The first sacrificial layer 1610 may be in contact with an upper surface of the first upper signal line 510b, and may be in contact with side surfaces of the first upper signal line 510b and the first lower signal line 510a. At least a portion of the first sacrificial layer 1610 may be disposed directly on the first gate insulating layer 141. The first sacrificial layer 1610 may be disposed between the first gate insulating layer 141 and the second gate insulating layer 142.

A second sacrificial layer 1620 may be disposed on the storage electrode 153 and the second signal line 520. The second sacrificial layer 1620 may include an amorphous silicon material. In the embodiments described above, the second sacrificial layer 620 may be disposed on the second gate conductive layer, but in the present embodiment, the second sacrificial layer 1620 may be disposed on the entirety or substantially on the entirety of the substrate 110. The second sacrificial layer 1620 may cover an upper surface and a side surface of the storage electrode 153. The second sacrificial layer 1620 may be in contact with an upper surface of the upper storage electrode 153b, and may be in contact with side surfaces of the upper storage electrode 153b and the lower storage electrode 153a. The second sacrificial layer 1620 may cover an upper surface and a side surface of the second signal line 520. The second sacrificial layer 1620 may be in contact with an upper surface of the second upper signal line 520b, and may be in contact with side surfaces of the second upper signal line 520b and the second lower signal line 520a. At least a portion of the second sacrificial layer 1620 may be disposed directly on the second gate insulating layer 142. The second sacrificial layer 1620 may be disposed between the second gate insulating layer 142 and the interlayer insulating layer 160.

The interlayer insulating layer 160, the second gate insulating layer 142, and the first gate insulating layer 141 may each have an opening 161 overlapping with the source electrode 173 of the transistor TR and the first region 131 of the semiconductor 130. The source electrode 173 of the transistor TR may be connected to the first region 131 of the semiconductor 130 through the opening 161. An opening 1613 may be formed in (e.g., may penetrate) the first sacrificial layer 1610, and an opening 1623 may be formed in (e.g., may penetrate) the second sacrificial layer 1620. The opening 1613 of the first sacrificial layer 1610 and the opening 1623 of the second sacrificial layer 1620 may overlap with the opening 161 of the interlayer insulating layer 160, the second gate insulating layer 142, and the first gate insulating layer 141. The source electrode 173 may extend through the interlayer insulating layer 160, the second sacrificial layer 1620, the second gate insulating layer 142, the first sacrificial layer 1610, and the first gate insulating layer 141 to be connected to the first region 131 of the semiconductor 130.

The interlayer insulating layer 160, the second gate insulating layer 142, and the first gate insulating layer 141 may each have an opening 163 overlapping with the drain electrode 175 of the transistor TR and the second region 133 of the semiconductor 130. The drain electrode 175 of the transistor TR may be connected to the second region 133 of the semiconductor 130 through the opening 163. An opening 1615 may be formed in (e.g., may penetrate) the first sacrificial layer 1610, and an opening 1625 may be formed in (e.g., may penetrate) the second sacrificial layer 1620. The opening 1615 of the first sacrificial layer 1610 and the opening 1625 of the second sacrificial layer 1620 may overlap with the opening 163 of the interlayer insulating layer 160, the second gate insulating layer 142, and the first gate insulating layer 141. The drain electrode 175 may extend through the interlayer insulating layer 160, the second sacrificial layer 1620, the second gate insulating layer 142, the first sacrificial layer 1610, and the first gate insulating layer 141 to be connected to the second region 133 of the semiconductor 130.

The interlayer insulating layer 160 and the second gate insulating layer 142 may have an opening 165 overlapping with the first signal line 510. The first connecting member 710 may be connected to the first signal line 510 through the opening 165. An opening 1611 may be formed in (e.g., may penetrate) the first sacrificial layer 1610, and an opening 1627 may be formed in (e.g., may penetrate) the second sacrificial layer 1620. The opening 1611 of the first sacrificial layer 1610 and the opening 1627 of the second sacrificial layer 1620 may overlap with the opening 165 of the interlayer insulating layer 160 and the second gate insulating layer 142. The first connection member 710 may extend through the interlayer insulating layer 160, the second sacrificial layer 1620, the second gate insulating layer 142, and the first sacrificial layer 1610 to be connected to the first signal line 510.

The interlayer insulating layer 160 may have an opening 167 overlapping with the second signal line 520. The second connecting member 720 may be connected to the first signal line 520 through the opening 167. An opening 1621 may also be formed in (e.g., may penetrate) the second sacrificial layer 1620. The opening 1621 of the second sacrificial layer 1620 may overlap with the opening 167 of the interlayer insulating layer 160. The second connecting member 720 may be connected to the second signal line 520 through the interlayer insulating layer 160 and the second sacrificial layer 1620.

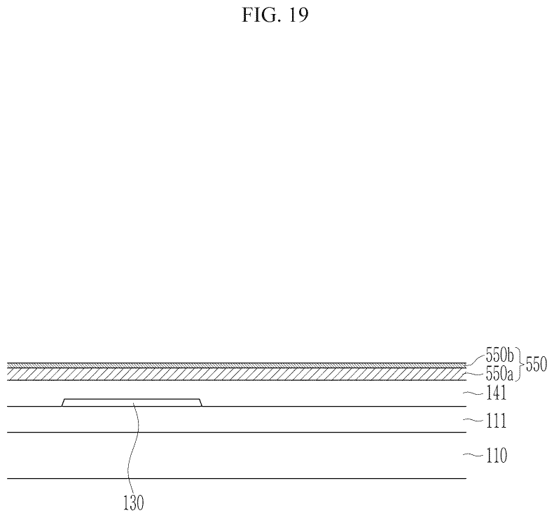

Next, a method of manufacturing a display device according to an embodiment will be described in more detail with reference to FIGS. 19 through 28.

FIG. 19 through FIG. 28 illustrate cross-sectional views of sequential processes of a manufacturing method of a display device according to an embodiment.

Referring to FIG. 19, a buffer layer 111, a semiconductor 130, and a first gate insulating layer 141 are sequentially formed on the substrate 110. A first gate material layer 550 is formed on the first gate insulating layer 141. The first gate material layer 550 may include a first lower gate material layer 550a and a first upper gate material layer 550b.

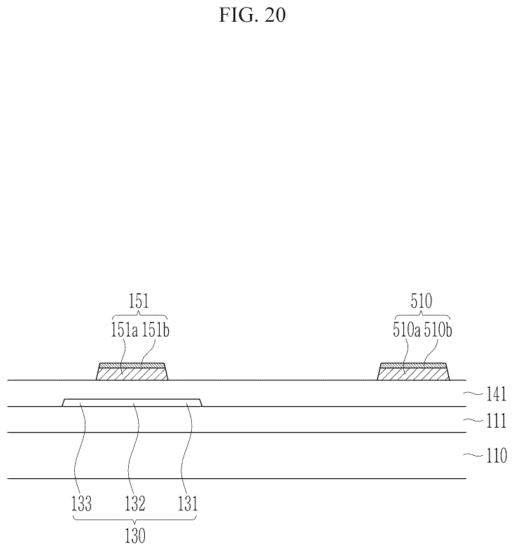

Referring to FIG. 20, the first gate material layer 550 is patterned by using a photo and etching process to form the gate electrode 151 and the first signal line 510. The gate electrode 151 may overlap with the semiconductor 130, and the first signal line 510 may be spaced apart from the gate electrode 151.

Subsequently, a doping process or a plasma treatment may be performed. A portion of the semiconductor 130 covered by the gate electrode 151 may be formed to be the channel 132, and portions of the semiconductor 130 not covered by the gate electrode 151 may be formed to be the first region 131 and the second region 133.

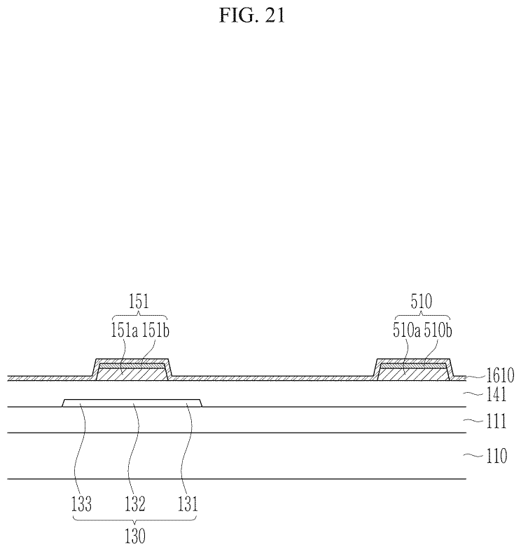

Referring to FIG. 21, the first sacrificial layer 1610 is formed by using an amorphous silicon material on the gate electrode 151 and the first signal line 510. The first sacrificial layer 1610 may be entirely disposed on the substrate 110. The first sacrificial layer 1610 may cover an upper surface and a side surface of the gate electrode 151. The first sacrificial layer 1610 may cover an upper surface and a side surface of the first signal line 510. At least a portion of the first sacrificial layer 1610 may be disposed directly on the first gate insulating layer 141.

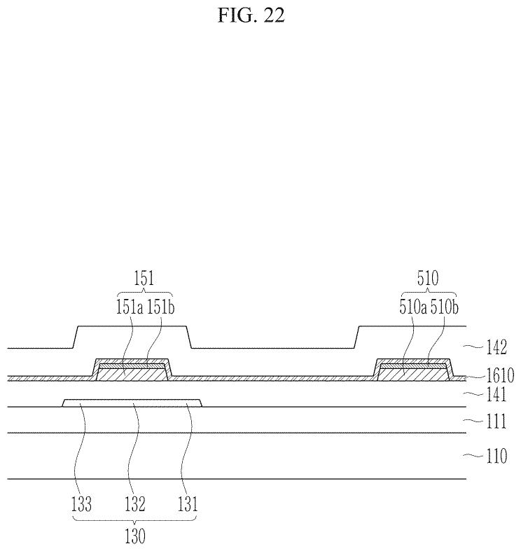

Referring to FIG. 22, a second gate insulating layer 142 is formed on the first sacrificial layer 1610. The second gate insulating layer 142 may be disposed directly on the first sacrificial layer 1610. The first sacrificial layer 1610 is disposed between the first gate insulating layer 141 and the second gate insulating layer 142.

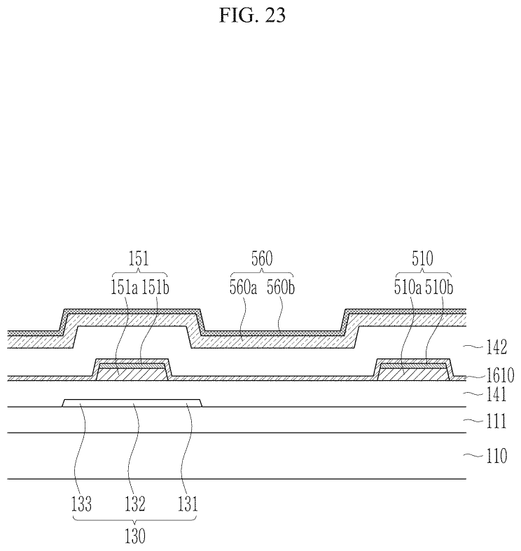

Referring to FIG. 23, a second gate material layer 560 is formed on the second gate insulating layer 142. The second gate material layer 560 may include a second lower gate material layer 560a and a second upper gate material layer 560b.

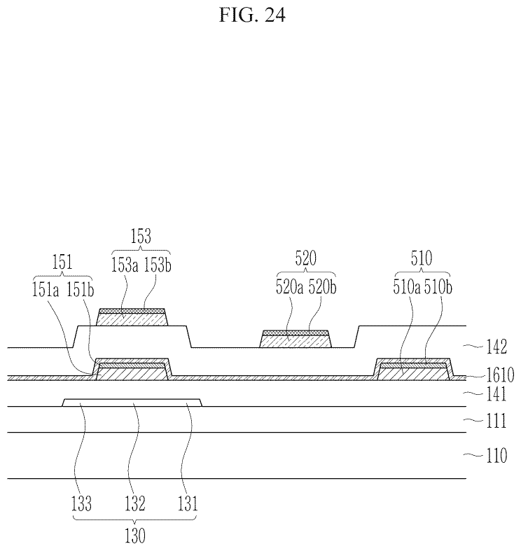

Referring to FIG. 24, the second gate material layer 560 is patterned by using a photo and etching process to form the storage electrode 153 and the second signal line 520. The storage electrode 153 may overlap with the gate electrode 151, and the second signal line 520 may be spaced apart from the storage electrode 153.

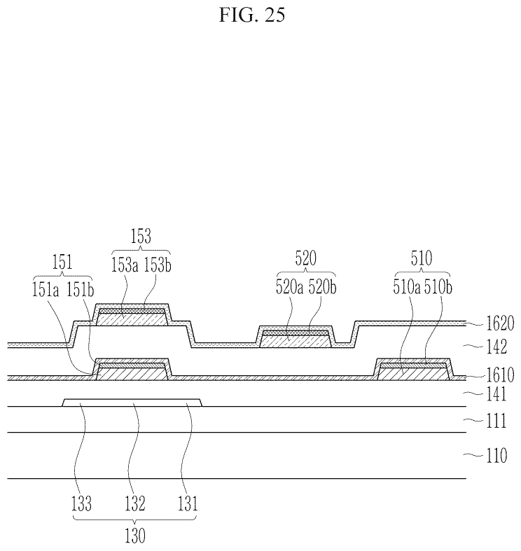

Referring to FIG. 25, the second sacrificial layer 1620 is formed by using an amorphous silicon material on the storage electrode 153 and the second signal line 520. The second sacrificial layer 1620 may be entirely disposed on the substrate 110. The second sacrificial layer 1620 may cover an upper surface and a side surface of the storage electrode 153. The second sacrificial layer 1620 may cover an upper surface and a side surface of the second signal line 520. At least a portion of the second sacrificial layer 1620 may be disposed directly on the second gate insulating layer 142.

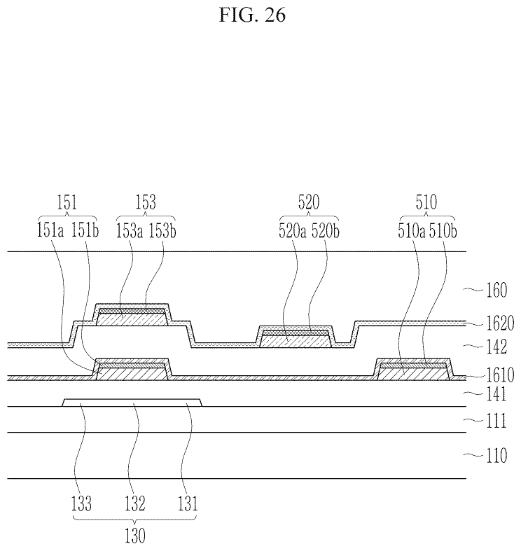

Referring to FIG. 26, an interlayer insulating layer 160 is formed on the second sacrificial layer 1620. The interlayer insulating layer 160 may be disposed directly on the second sacrificial layer 1620. The second sacrificial layer 1620 is disposed between the second gate insulating layer 142 and the interlayer insulating layer 160.

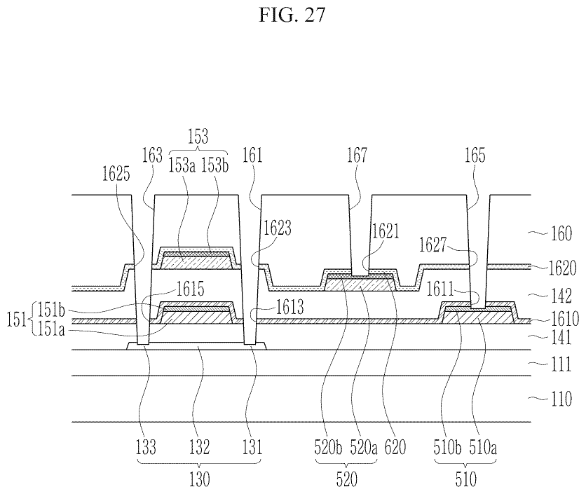

Referring to FIG. 27, the interlayer insulating layer 160, the second gate insulating layer 142, and the first gate insulating layer 141 are patterned using a photo and etching process to form openings 161, 163, 165, and 167. The openings 161, 163, 165, and 167 may include the opening 161 overlapping with the first region 131 of the semiconductor 130, the opening 163 overlapping with the second region 133 of the semiconductor 130, the opening 165 overlapping with the first signal line 510, and the opening 167 overlapping with the second signal line 520.

The second sacrificial layer 1620 and the first sacrificial layer 1610 may also be patterned together in a process of patterning the interlayer insulating layer 160, the second gate insulating layer 142, and the first gate insulating layer 141. Openings 1621, 1623, 1625, and 1627 may be formed in (e.g., may penetrate) the second sacrificial layer 1620, and openings 1611, 1613, and 1615 may be formed in (e.g., may penetrate) the first sacrificial layer 1610.

Subsequently, an annealing process may be performed, and a buffered oxide etch (BOE) cleaning process may be performed.

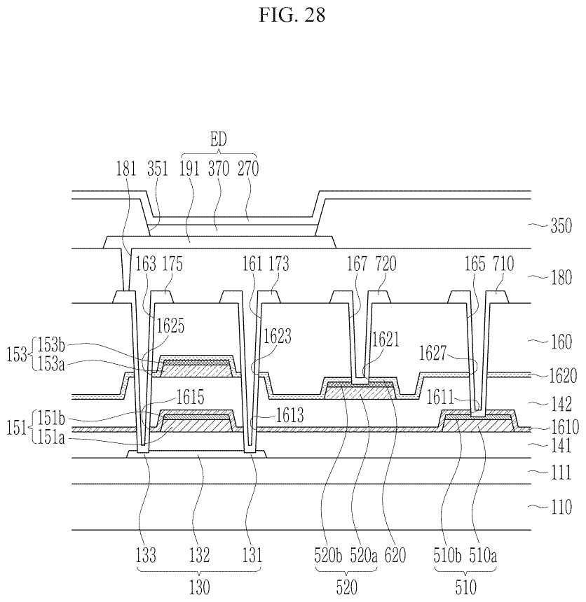

Referring to FIG. 28, a source electrode 173, a drain electrode 175, a first connecting member 710, and a second connecting member 720 are formed by depositing a metal material, and performing a photo and etching process. The source electrode 173 may be connected to the first region 131 of the semiconductor 130, and the drain electrode 175 may be connected to the second region 133 of the semiconductor 130. The first connecting member 710 may be connected to the first signal line 510, and the second connecting member 720 may be connected to the second signal line 520.

The passivation layer 180 is formed on the source electrode 173, the drain electrode 175, the first connecting member 710, and the second connecting member 720, and the first electrode 191 is formed on the passivation layer 180.

The partition wall 350 is formed on the first electrode 191 and the passivation layer 180. A pixel opening 351 is formed by patterning the partition wall 350, and an emission layer 370 is formed in the pixel opening 351. The second electrode 270 is formed on the emission layer 370 and the partition wall 350. In some embodiments, an encapsulation layer may be disposed on the second electrode 270.

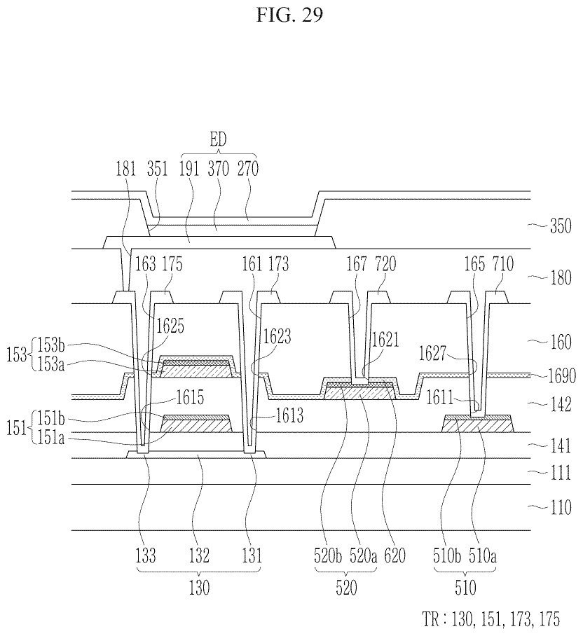

Next, a display device according to an embodiment will be described in more detail with reference to FIG. 29.

FIG. 29 illustrates a cross-sectional view of a display device according to an embodiment.

The display device illustrated in FIG. 29 may be the same or substantially the same as the display device described above with reference to FIG. 18, and thus, the differences are mainly described in more detail, and redundant description of the same or substantially the same components therebetween may not be repeated. The present embodiment may be different from the embodiments described above, in that the first sacrificial layer is omitted, which will be further described in more detail below.

Referring to FIG. 29, a display device according to an embodiment may include a substrate 110, a transistor TR positioned on the substrate 110, and a light emitting diode ED connected to the transistor TR. In addition, a plurality of signal lines may be positioned on the substrate 110. The signal lines may include a first signal line 510, a second signal line 520, and the like.

In the embodiments described above, the first sacrificial layer 1610 may be disposed on the first signal line 510 and the second sacrificial layer 1620 may be disposed on the second signal line 520. In the present embodiment, a separate sacrificial layer may not be disposed on the first signal line 510, and a sacrificial layer 1690 may be disposed on the second signal line 520. However, the present disclosure is not limited thereto, and a separate sacrificial layer may not be disposed on the second signal line 520, but a sacrificial layer may be disposed on the first signal line 510.

The sacrificial layer 1690 may be disposed on the storage electrode 153 and the second signal line 520. The sacrificial layer 1690 may include an amorphous silicon material. The sacrificial layer 1690 may be entirely disposed on (e.g., disposed on the entirety or substantially the entirety of) the substrate 110. The sacrificial layer 1690 may cover an upper surface and a side surface of the storage electrode 153. The sacrificial layer 1690 may cover an upper surface and a side surface of the second signal line 520. At least a portion of the sacrificial layer 1690 may be disposed directly on the second gate insulating layer 142. The sacrificial layer 1690 may be disposed between the second gate insulating layer 142 and the interlayer insulating layer 160.

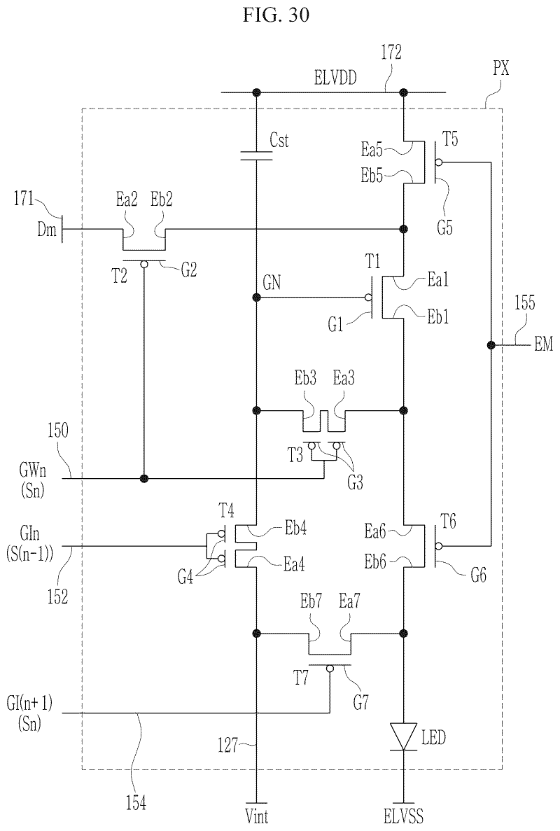

As described above, a display device according to one or more embodiments may include a plurality of pixels, and each of the pixels may include a plurality of transistors, and a light emitting diode connected to the transistors. Hereinafter, examples of the plurality of transistors that may be included in one pixel of a display device according to an embodiment, and a plurality of signal lines connected thereto, will be described in more detail with reference to FIG. 30.

FIG. 30 illustrates a circuit diagram of a pixel of a display device according to an embodiment.

Referring to FIG. 30, the display device according to an embodiment includes a plurality of pixels PX for displaying an image, and a plurality of signal lines 127, 150, 152, 154, 155, 171, and 172. One pixel PX may include a plurality of transistors T1, T2, T3, T4, T5, T6, and T7, a capacitor Cst, and at least one light emitting diode LED that are connected to the signal lines 127, 150, 152, 154, 155, 171, and 172. In the present embodiment, an example in which one pixel PX includes one light emitting diode LED is mainly described, but the present disclosure is not limited thereto, and one pixel PX may include a plurality of light emitting diodes.

The signal lines 127, 150, 152, 154, 155, 171, and 172 may include an initialization voltage line 127, a plurality of scan lines 150, 152, and 154, an emission control line 155, a data line 171, and a driving voltage line 172. At least some of the signal lines 127, 150, 152, 154, 155, 171, and 172 may correspond to the first signal line 510 and the second signal line 520 described above. The first signal line 510 and the second signal line 520 may be connected to the transistor by the first connecting member 710 and the second connecting member 720. The initialization voltage line 127 may transfer an initialization voltage Vint. The scan lines 150, 152, and 154 may transfer scan signals GWn, GIn, and GI(n+1), respectively, where n is a natural number. The scan signals GWn, GIn, and GI(n+1) may transfer a gate-on voltage and a gate-off voltage that can turn on or turn off the transistors T2, T3, T4, and T7 included in the pixel PX.

The scan lines 150, 152, and 154 connected to the pixel PX may include a first scan line 150 through which the scan signal GWn may be transferred, a second scan line 152 through which the scan signal GIn having a gate-on voltage may be transferred at a different time from that of the first scan line 150, and a third scan line 154 through which the scan signal GI(n+1) may be transferred. In the present embodiment, an example in which the second scan line 152 transfers the gate-on voltage at a time that is earlier than that of the first scan line 150 will be mainly described. For example, when the scan signal GWn is an n^{th} scan signal Sn (n being a natural number that is equal to or greater than 1) from among the scan signals applied during one frame, the scan signal GIn may be a previous-stage scan signal, such as an (n−1)^{th} scan signal, and the scan signal GI(n+1) may be an n^{th} scan signal Sn. However, the present embodiment is not limited thereto, and the scan signal GI(n+1) may be a scan signal that is different from the n^{th} scan signal Sn.

The emission control line 155 may transfer a control signal, and in more detail, may transfer an emission control signal EM capable of controlling the emission of the light emitting diode LED included in the pixel PX. The control signal transferred by the emission control line 155 may transfer the gate-on voltage and the gate-off voltage, and may have a waveform that is different from that of the scan signal transferred by the scan lines 150, 152, and 154.

The data line 171 may transfer a data signal Dm, and the driving voltage line 172 may transfer a driving voltage ELVDD. The data signal Dm may have a different voltage level depending on an image signal input into the display device, and the driving voltage ELVDD may have a constant or substantially constant level.

The display device according to an embodiment may further include a driver (e.g., a scan/emission driver, a data driver, and/or the like) that transfers the signals to the signal lines 127, 150, 152, 154, 171, and 172.

The transistors T1, T2, T3, T4, T5, T6 and T7 included in the pixel PX may include a first transistor T1, a second transistor T2, a third transistor T3, a fourth transistor T4, a fifth transistor T5, a sixth transistor T6, and a seventh transistor T7.

The first scan line 150 may transfer the scan signal GWn to the second transistor T2 and the third transistor T3. The second scan line 152 may transfer the scan signal GIn to the fourth transistor T4. The third scan line 154 may transfer the scan signal GI(n+1) to the seventh transistor T7. The emission control line 155 may transfer the emission control signal EM to the fifth transistor T5 and the sixth transistor T6.

The gate electrode G1 of the first transistor T1 is connected to a first end of the capacitor Cst through a driving gate node GN, a first electrode Ea1 of the first transistor T1 is connected to the driving voltage line 172 via the fifth transistor T5, and a second electrode Eb1 of the first transistor T1 is connected to an anode of the light emitting diode LED via the sixth transistor T6. The first transistor T1 may receive the data signal Dm transferred by the data line 171 depending on a switching operation of the second transistor T2, to supply a driving current Id to the light emitting diode LED.

The gate electrode G2 of the second transistor T2 is connected to the first scan line 150, a first electrode Ea2 of the second transistor T2 is connected to the data line 171, and a second electrode Eb2 of the second transistor T2 is connected to the first electrode Ea1 of the first transistor T1, and to the driving voltage line 172 via the fifth transistor T5. The second transistor T2 may be turned on depending on the scan signal GWn received through the first scan line 150, to transfer the data signal Dm transferred from the data line 171 to the first electrode Ea1 of the first transistor T1.

A gate electrode G3 of the third transistor T3 is connected to the first scan line 150, and a first electrode Ea3 of the third transistor T3 is connected to the second electrode Eb1 of the first transistor T1, and to the anode of the light emitting diode LED via the sixth transistor T6. A second electrode Eb3 of the third transistor T3 is connected to a second electrode Eb4 of the fourth transistor T4, the first end of the capacitor Cst, and the gate electrode G1 of the first transistor T1. The third transistor T3 may be turned on depending on the scan signal GWn transferred through the first scan line 150, to connect the gate electrode G1 and the second electrode Eb1 of the first transistor T1 to each other, such that the first transistor T1 is diode-connected.

The gate electrode G4 of the fourth transistor T4 is connected to the second scan line 152, a first electrode Ea4 of the fourth transistor T4 is connected to a terminal (e.g., the initialization voltage line 127) of an initialization voltage Vint, and the second electrode Eb4 of the fourth transistor T4 is connected to the first end of the capacitor Cst via the second electrode Eb3 of the third transistor T3, and to the gate electrode G1 of first transistor T1. The fourth transistor T4 is turned on by the scan signal GIn transferred through the second scan line 152 to transfer the initialization voltage Vint to the gate electrode G1 of the first transistor T1, in order to perform an initializing operation for initializing a voltage of the gate electrode G1 of the transistor T1.

The gate electrode G5 of the fifth transistor T5 is connected to the emission control line 155, a first electrode Ea5 of the fifth transistor T5 is connected to the driving voltage line 172, and a second electrode Eb5 of the fifth transistor T5 is connected to the first electrode Ea1 of the first transistor T1 and to the second electrode Eb2 of the second transistor T2.

A gate electrode G6 of the sixth transistor T6 is connected to the emission control line 155, and a first electrode Ea6 of the sixth transistor T6 is connected to the second electrode Eb1 of the first transistor T1 and the first electrode Ea3 of the third transistor T3. A second electrode Eb6 of the sixth transistor T6 is electrically connected to the anode of the light emitting diode LED. The fifth transistor T5 and the sixth transistor T6 are concurrently (e.g., simultaneously or substantially simultaneously) turned on with each other depending on the emission control signal EM transferred through the emission control line 155, and thus, the driving voltage ELVDD may be compensated for through the diode-connected first transistor T1 to be transmitted to the light emitting diode LED.

A gate electrode G7 of the seventh transistor T7 is connected to the third scan line 154, and a first electrode Ea7 of the seventh transistor T7 is connected to the second electrode Eb6 of the sixth transistor T6 and the anode of the light emitting diode LED. A second electrode Eb7 of the seventh transistor T7 is connected to the terminal (e.g., the initialization voltage line 127) of the initialization voltage Vint and the first electrode Ea4 of the fourth transistor T4.

The transistors T1, T2, T3, T4, T5, T6, and T7 may be P-type channel transistors, such as PMOS transistors, but the present disclosure is not limited thereto, and at least one of the transistors T1, T2, T3, T4, T5, T6, and T7 may be an N-type channel transistor.

The first end of the capacitor Cst is connected to the gate electrode G1 of the first transistor T1 as described above, and a second end of the capacitor Cst is connected to the driving voltage line 172. A cathode of the light emitting diode LED may be connected to a terminal of the common voltage ELVSS to receive the common voltage ELVSS.

Although the pixel PX is illustrated as including seven transistors T1 to T7, one storage capacitor Cst, and one light emitting diode LED, the present disclosure is not limited thereto, and the number of transistors, the number of capacitors, the number of light emitting diodes, and their connection relationships may be variously modified as needed or desired, as would be appreciated by those having ordinary skill in the art.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

### DESCRIPTION OF SYMBOLS

110: substrate
130: semiconductor
141: first gate insulating layer
142: second gate insulating layer
151: gate electrode
153: storage electrode
160: interlayer insulating layer
510: first signal line
520: second signal line
550: first gate material layer
560: second gate material layer
610, 1610: first sacrificial layer
620, 1620: second sacrificial layer
650: first sacrificial material layer
660: second sacrificial material layer
710: first connecting member
720: second connecting member

What is claimed is:

1. A display device comprising:
a substrate;
a semiconductor on the substrate;
a first gate insulating layer on the semiconductor;
a gate electrode on the first gate insulating layer, and overlapping with the semiconductor;
a signal line spaced from the gate electrode;
a sacrificial layer on the signal line, and comprising an amorphous silicon material;
an interlayer insulating layer on the gate electrode and the sacrificial layer;
a source electrode on the interlayer insulating layer, and connected to a first region of the semiconductor;
a drain electrode on the interlayer insulating layer, and connected to a second region of the semiconductor; and
a connecting member on the interlayer insulating layer, and connected to the signal line.

2. The display device of claim 1, further comprising:
a second gate insulating layer on the gate electrode; and
a storage electrode on the second gate insulating layer, and overlapping with the gate electrode,
wherein the signal line comprises:
a first signal line at a same layer as that of the gate electrode; and
a second signal line at a same layer as that of the storage electrode.

3. The display device of claim 2, wherein the sacrificial layer comprises:
a first sacrificial layer directly on the first signal line; and
a second sacrificial layer directly on the second signal line.

4. The display device of claim 3, wherein:
the first sacrificial layer is further directly on the gate electrode; and
the second sacrificial layer is further directly on the storage electrode.

5. The display device of claim 4, wherein:
the first sacrificial layer has same planar shapes as those of the gate electrode and the first signal line; and
the second sacrificial layer has same planar shapes as those of the storage electrode and the second signal line.

6. The display device of claim 3, wherein the connecting member comprises:
a first connecting member connected to the first signal line; and
a second connecting member connected to the second signal line,
wherein the first connection member extends through the interlayer insulating layer, the second gate insulating layer, and the first sacrificial layer to be connected to the first signal line, and
wherein the second connection member extends through the interlayer insulating layer and the second sacrificial layer to be connected to the second signal line.

7. The display device of claim 6, wherein:
a bottom surface of the first connecting member is in contact with the first signal line, and a side surface of the first connecting member is surrounded by the interlayer insulating layer, the second gate insulating layer, and the first sacrificial layer; and
a bottom surface of the second connecting member is in contact with the second signal line, and a side surface of the second connecting member is surrounded by the interlayer insulating layer and the second sacrificial layer.

8. The display device of claim 3, wherein the first sacrificial layer and the second sacrificial layer are on an entirety of the substrate.

9. The display device of claim 2, wherein the sacrificial layer is directly on the second signal line and the storage electrode.

10. The display device of claim 1, wherein the signal line comprises:
a lower signal line comprising aluminum; and
an upper signal line on the lower signal line, and comprising titanium.

11. A manufacturing method of a display device, comprising:
forming a semiconductor on a substrate;
forming a first gate insulating layer on the semiconductor;
forming a gate electrode on the first gate insulating layer;
forming a signal line spaced from the gate electrode;
forming a sacrificial layer on the gate electrode and the signal line by using an amorphous silicon material;
forming an interlayer insulating layer on the sacrificial layer; and
forming a source electrode, a drain electrode, and a connecting member on the interlayer insulating layer,
wherein the source electrode is connected to a first region of the semiconductor, the drain electrode is connected to a second region of the semiconductor, and the connecting member is connected to the signal line.

12. The manufacturing method of claim 11, further comprising:
forming a second gate insulating layer on the gate electrode; and
forming a storage electrode on the second gate insulating layer to overlap with the gate electrode,
wherein the signal line comprises:
a first signal line formed in a same process as that of the forming of the gate electrode; and
a second signal line formed in a same process as that of the forming of the storage electrode.

13. The manufacturing method of claim 12, wherein the sacrificial layer comprises:
a first sacrificial layer directly on the first signal line; and
a second sacrificial layer directly on the second signal line.

14. The manufacturing method of claim 13, wherein the gate electrode, the first signal line, and the first sacrificial layer are formed by successively depositing a first gate material layer and a first sacrificial material layer on the first gate insulating layer, and patterning the first gate material layer and the first sacrificial material layer, and
wherein the storage electrode, the second signal line, and the second sacrificial layer are formed by successively depositing a second gate material layer and a second sacrificial material layer on the second gate insulating layer, and patterning the second gate material layer and the second sacrificial material layer.

15. The manufacturing method of claim 14, wherein the first sacrificial layer is patterned with the gate electrode and the first signal line by using a same mask, and
wherein the second sacrificial layer is patterned with the storage electrode and the second signal line by using a same mask.

16. The manufacturing method of claim 13, wherein the connecting member comprises:
a first connecting member connected to the first signal line; and
a second connecting member connected to the second signal line,
wherein the first connection member extends through the interlayer insulating layer, the second gate insulating layer, and the first sacrificial layer to be connected to the first signal line, and
wherein the second connection member extends through the interlayer insulating layer and the second sacrificial layer to be connected to the second signal line.

17. The manufacturing method of claim 16, wherein:
a bottom surface of the first connecting member is in contact with the first signal line, and a side surface of the first connecting member is surrounded by the interlayer insulating layer, the second gate insulating layer, and the first sacrificial layer; and
wherein a bottom surface of the second connecting member is in contact with the second signal line, and a side surface of the second connecting member is surrounded by the interlayer insulating layer and the second sacrificial layer.

18. The manufacturing method of claim 13, wherein the first sacrificial layer and the second sacrificial layer are formed entirely on the substrate.

19. The manufacturing method of claim 12, wherein the sacrificial layer is directly on the second signal line and the storage electrode.

20. The manufacturing method of claim 11, wherein the signal line comprises:
a lower signal line comprising aluminum; and
an upper signal line on the lower signal line, and comprising titanium.
